(19) United States
(12) Patent Application Publication
(10) Pub. No.: US 2004/0069409 A1
(43) Pub. Date: Apr. 15, 2004

(54) Front opening unified pod door opener with dust-proof device

(76) Inventors: Hippo Wu, Hsinchu (TW); James Shyu, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/065,383

(22) Filed: Oct. 11, 2002

(51) Int. Cl. H01L 21/306

(52) U.S. Cl. 156/345.31

(57) ABSTRACT

A front opening unified pod (FOUP) with a dust-proof device that is set up beside a station for processing 12-inch wafers. The FOUP door opener opens up to allow wafers going to or from the FOUP while preventing external dust particles from diffusing into the station. The FOUP door opener includes an inner door and an outer door. The dust-proofing device is set up close to the FOUP door opener next to a nitrogen load-lock area inside the station. The dust-proofing device has a gas pump for pumping gases, a gas filter connected to the gas outlet port of the gas pump for removing dust particles, a gas outflow unit connected to the gas outlet port of the gas filter for blowing a layer of laminar gas and a gas inflow unit connected to the gas inlet port of the gas pump so that gas blown out from the gas outflow unit is returned to the gas pump via the gas inflow unit. The FOUP door opener prevents dust particles from contaminating the loading area of the furnace while using very little nitrogen.

### BACKGROUND OF INVENTION

1. Field of Invention

The present invention relates to a semiconductor manufacturing apparatus. More particularly, the present invention relates to a front opening unified pod door opener with a dust-proof device for a 12-inch wafer processing station.

2. Description of Related Art

As the level of integration of semiconductor devices continues to increase, manufacturing precision has become increasingly important. Should there be any errors or contamination, the integrated circuits within each silicon wafer may be irreparably damaged and hence must be scrapped leading to a tremendous waste.

In most semiconductor fabrication processes, the manufacturing stations are arranged into a plurality of modules (for fabrication/transmission/storage/safetylocks/reactive gases). A wafer transfer system is used to transfer silicon wafers between the processing modules and respective storage modules. In general, wafers are snatched by a robot blade from a wafer holder and then transferred to a processing chamber. After processing inside the chamber, the wafers are returned back to the wafer holder so that a series of other fabrication steps are also carried out.

A conventional 8-inch wafer manufacturing system uses a wafer holder called the standard mechanical interface (SMIF). However, with recent advances in semiconductor manufacturing technologies, the silicon wafer has increased in size to 12 inches. A 12-inch silicon wafer holder is slightly different from a conventional 8-inch holder and is often referred to as a front opening unified pod (FOUP). The front opening unified pod is a sealed area for holding silicon wafers so that dust and contaminants in the atmosphere are kept away. Although the FOUP has high degree of interior cleanliness, the loading of wafers into the a FOUP by opening and closing the FOUP door demands the injection of a large amount of nitrogen to prevent the air inside the FOUP from affecting the low oxygen atmosphere inside the processing chamber. In addition, the opening and closing of the FOUP door often disturbs the peripheral environment and stirs up dust particles at the back of each wafer leading to the wafer contamination. Using a reaction furnace as an example, the station has a FOUP door opener consisting of an inner door and an outer door. By careful control of the inner door and the outer door, the effect of dust particles on the station is reduced.

FIG. 1 is a top view of a conventional 12-inch wafer reaction furnace. As shown in FIG. 1, the reaction furnace 100 includes a reaction chamber 102, a nitrogen load-lock area 104, a robot blade 106 and a front opening unified pod (FOUP) door opener 108. The nitrogen load-lock area 104 is a low oxygen environment. A FOUP 110 is installed on the FOUP door opener 108. The FOUP door opener 108 is a device for opening up the reaction furnace 100 so that silicon wafers may transfer into and out of the nitrogen load-lock area 104. The FOUP door opening 108 includes an inner door 108a, an outer door 108b and a nitrogen nozzle 108c. The inner door 108a is closer to the FOUP 110 while the outer door 108b is closer to the nitrogen load-lock area 104. The nitrogen nozzle 108c is set up between the inner door 108a and the outer door 108b. To provide a better seal between the FOUP 110 and the FOUP door opener 108, the FOUP 110 and the FOUP door opener 108 are fastened together through a clamp 112.

To transfer wafers from the FOUP 110 into the reaction chamber 102, the inner door 108a of the FOUP door opener 108 is opened. A jet of nitrogen is immediately blown from the nitrogen nozzle 108c into the FOUP 110 continuously for a few minutes so that oxygen concentration inside the FOUP 110 is lowered. Thereafter, the outer door 108b of the FOUP door opener 108 is opened so that the robot blade 106 is able to extend into the FOUP 110 and fetch a wafer. The wafer is moved into the reaction furnace 100 and placed on a wafer boat. After all the wafers in the FOUP 110 are moved to the wafer boat, the inner door 108a and the outer door 108b of the FOUP door opener 108 are closed. The aforementioned steps are repeated to bring in another wafer from another FOUP to the wafer boat until the entire wafer boat is filled (a total of 120 wafers, in general). Thereafter, the wafer boat is transferred to the reaction chamber 102 for conducting a necessary reaction. Similarly, to load the wafers into the FOUP 110, the wafer boat is moved away from the reaction chamber 102. Thereafter, the inner door 108a of the FOUP door opener 108 is opened and a jet of nitrogen is blown from the nitrogen nozzle 108c into the FOUP 110 continuously for a few minutes. The outer door 108b is next opened so that the robot blade 106 can pick up a wafer from the wafer boat and deliver the wafer into the FOUP 110. After the FOUP 110 is completely filled, the inner door 108a and the outer door 108b of the FOUP door opener 108 is closed. The aforementioned processes are repeated, each time removing some of the remaining wafers on the wafer boat to another FOUP 110, until all the wafers inside the wafer boat are removed.

Since the nitrogen load-lock region 104 must contain very little oxygen, opening up the reaction furnace 100 demands the ejection of a stream of nitrogen from the nitrogen nozzle 108c into the FOUP 110 to lower the concentration of oxygen inside the FOUP 110. Otherwise, air within the FOUP 110 may leak into the nitrogen load-lock area 104. The blowing of nitrogen into the FOUP 110 for a few minutes to reduce the concentration of oxygen inside the FOUP not only consumes large quantity of nitrogen, but also wastes time as well.

Furthermore, the step of opening up the inner door 108a of the FOUP door opener 108 and the blowing of nitrogen into the interior of FOUP 110 through the nitrogen nozzle 108c also stirs up dust particles inside the FOUP 110 as well as on the backside of the wafers. Once the outer door 108b is opened, these micro-particles will easily diffuse into the nitrogen load-lock area 104 and contaminate that area. Some of these dust particles may finally settle on the surface of the wafers leading to undesirable effects.

In addition, to prevent outside air and dust particles from entering the reaction chamber through the FOUP door opener 108, a perfect seal between the FOUP 110 and the FOUP door opener 108 must be maintained. Hence, the FOUP 110 and the FOUP door opener 108 must be tightly joined with the clamp 112.

### SUMMARY OF INVENTION

Accordingly, one object of the present invention is to provide a front opening unified pod (FOUP) door opener with a dust-proof device capable of preventing dust particles and air from entering the nitrogen load-lock area inside a processing station and leakage of nitrogen out from the nitrogen load-lock area.

A second object of this invention is to provide a front opening unified pod (FOUP) door opener with a dust-proof device that does not need a clamp to join the FOUP and the FOUP door opener tightly together. This is because even a loose seal has little effect on the nitrogen load-lock area of a processing station.

A third object of this invention is to provide a front opening unified pod (FOUP) door opener with a dust-proof device capable of directly transferring a wafer from the FOUP to a wafer boat and vice versa so that transfer time is shortened and productivity is increased.

A fourth object of this invention is to provide a front opening unified pod (FOUP) door opener with a dust-proof device capable of saving nitrogen so that cost of providing the nitrogen is reduced.

To achieve these and other advantages and in accordance with the purpose of the invention, as embodied and broadly described herein, the invention provides a front opening unified pod (FOUP) door opener with a dust-proof device. The door opener is particularly suitable for opening up a 12-inch wafer-processing station (such as a reaction furnace), picking up a wafer from the FOUP and then loading the wafer into the reaction chamber of the station. The FOUP door opener mainly includes an inner door and an outer door. The dust-proofing device is installed on the side of the FOUP door opener nearer to the nitrogen load-lock area of the reaction furnace. The dust-proofing device includes a gas pump for pumping gases, a gas filter connected to the gas outlet port of the gas pump for filtering out dust particles from the gas, a gas outflow unit connected to the gas outlet port of the gas filter for producing a laminar flow of gas and an gas suction unit connected to gas intake port of the gas pump. Ultimately, the laminar flow ejected from the gas outflow unit is taken up by the gas suction unit and returned to the pumping device in a complete cycle. The gas outflow unit and the gas suction unit are positioned to face each other but are separated from each other by a spatial gap. The spatial gap is a channel for delivering wafers into and out of the reaction furnace. Furthermore, a curtain created by the gas outflow unit and the gas inflow unit flows in a direction parallel to the respective surfaces of the wafers so that the front and back surfaces of the wafers are swept.

The dust proof front opening unified pod (FOUP) door opener for processing 12 inch wafers inside a station (such as a reaction furnace) according to this invention may have a dust-proofing device that blows nitrogen to form a nitrogen curtain. Similarly, the nitrogen curtain flows in a direction parallel to the surfaces of the respective wafers. Since each wafer entering or leaving the FOUP must pass through the gas curtain provided by the dust-proofing device, micro-particles on the surface of the wafers are removed and filtered away. Thus, the entrance of micro-particles and air into the nitrogen load-lock area is prevented.

Because any wafer going into or out of the FOUP has to pass through the dust-proofing device, the nitrogen load-lock area (low oxygen area) is little affected even if the FOUP door opener and the FOUP are not tightly sealed. Consequently, there is little need to install special clamps to bind the FOUP door opener and the FOUP tightly together.

In addition, the installation of a dust-proofing device on the front opening unified pod (FOUP) door opener of a station (such as a reaction furnace) for processing 12 inch wafers has other advantages too. Since wafers that move into or out of the FOUP must pass through the dust-proofing device, the wafers can be transferred directly from the FOUP to a wafer boat and vice versa. Without the need to blow nitrogen into the FOUP for long periods of time, processing time as well as nitrogen are saved and overall productivity is increased.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic top view of a conventional 12-inch wafer reaction furnace;

FIG. 2 is a schematic top view of a reaction furnace having a dust-proof FOUP door opener according to one embodiment of this invention;

FIGS. 3A and 3B are schematic perspective views of the structure of a dust-proofing device according to one preferred embodiment of this invention; and

FIG. 4 is a schematic diagram showing a wafer passing through the dust-proofing device according to this invention.

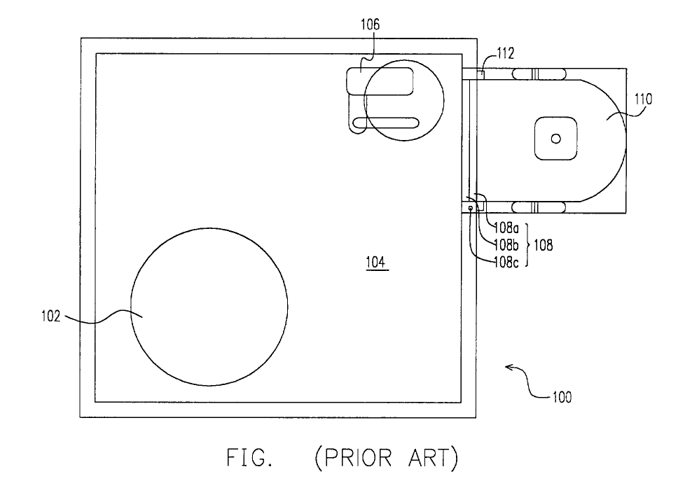

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

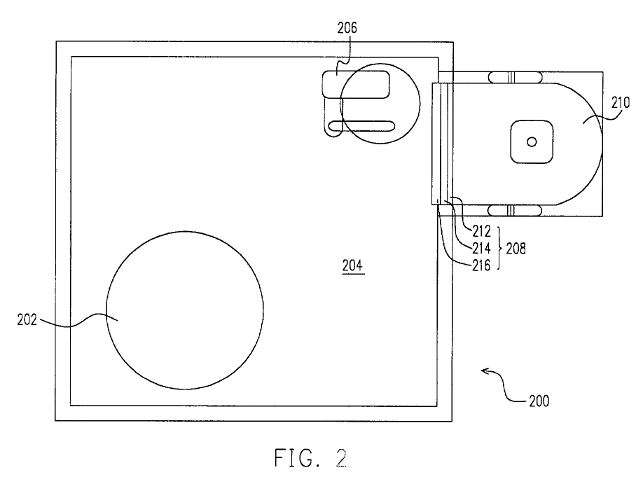

FIG. 2 is a schematic top view of a reaction furnace having a dust-proof FOUP door opener according to one embodiment of this invention. As shown in FIG. 2, the reaction furnace 200 includes a reaction chamber 202, a nitrogen load-lock area 204, a robot blade 206 and a front opening unified pod (FOUP) door opener 208. A front opening unified pod 210 is set up next to the FOUP door opener 208. The FOUP door opener 208 includes an inner door 212, an outer door 214 and a dust-proofing device 216. The inner door 212 is close to the FOUP 210 while the outer door 214 is inserted between the inner door 212 and the dust-proofing device 216. The dust-proofing device 216 is set up next to the nitrogen load-lock area 204.

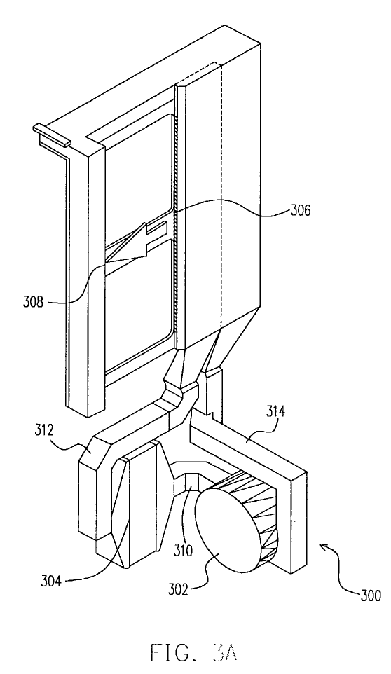

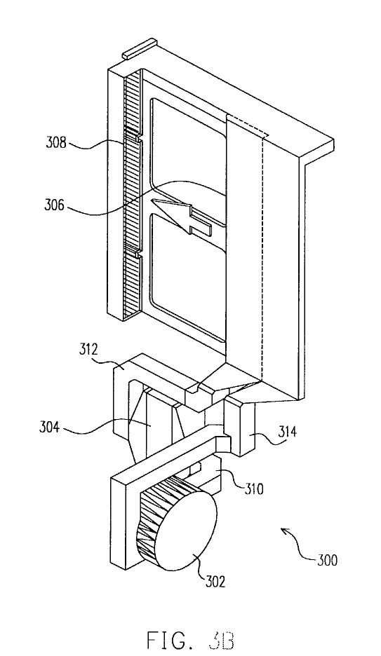

FIGS. 3A and 3B are schematic perspective views of the structure of a dust-proofing device according to one preferred embodiment of this invention. FIG. 3B is a view after turning the structure in FIG. 3A around by 90°. As shown in FIGS. 3A and 3B, the dust-proofing device 300 includes a gas pump 302, a gas filter 304, a gas outflow unit 306, a gas suction unit 308, a first pipeline 310, a second pipeline 312 and a third pipeline 314. The first pipeline 310 connects to the outlet port of the gas pump 302 and the inlet port of the gas filter 304. The second pipeline 312 connects to the outlet port of the gas filter 304 and the gas outflow unit 306. The third pipeline 314 connects to the gas suction unit 308 and the inlet port of the gas pump 302.

The gas pump 302 can be, for example, an air-blow drum for pumping gases. The gas filter 304 filters out micro-particles in the gas. The gas outflow unit 306 is a setup with many small pipelines therein for blowing gases out to form a laminar flow layer such that the laminar layer of gas is eventually taken back in by the gas suction unit 308. The laminar gas current flowing from the gas outflow unit 306 to the gas suction unit 308 forms a gas curtain. The space between the gas outflow unit 306 and the gas suction unit 308 constitute a channel to the FOUP.

The following is a brief description of the operating principle of the dust-proofing device. First, the gas pump 302 is triggered to pump and compress gas (nitrogen). Gas flows through the first pipeline 310 to the gas filter 304. On passing the gas filter 304, dust particles or other impurities in the gas are filtered away. The filtered gas passes onto the gas outflow unit 306 via the second pipeline 312. The gas is forced through the many small pipelines inside the gas outflow unit 306 to produce a laminar layer of gas and form a gas curtain that heads towards the gas suction unit 308. Thereafter, the gas is sucked into the gas suction unit 308 and returned to the gas pump 302 via the third pipeline 314. Hence, gas circulates around the dust-proofing device 300 and removes most suspended dust particles from the gas so that the quality of gas blown out from the gas outflow unit 306 is cleaner.

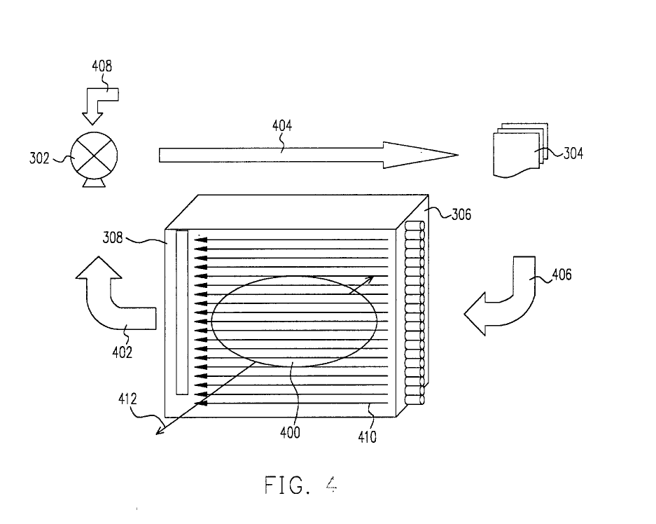

FIG. 4 is a schematic diagram showing a wafer passing through the dust-proofing device according to this invention. As shown in FIG. 4, elements identical to the ones shown in FIGS. 3A and 3B are labeled identically. In FIG. 4, the arrow 402, the arrow 404, the arrow 406, the arrow 408 and the arrow 410 all indicate the flow direction of gas (nitrogen). The arrow 408 indicates the flow direction of replenishing gas (nitrogen). Another arrow 412 indicates the direction of movement of a silicon wafer 400.

As shown in FIG. 4, gaseous nitrogen passing through the gas pump 302 is compressed. The compressed nitrogen is filtered in the gas outflow unit 306. The filtered nitrogen is forced through many small pipelines inside the gas outflow unit 306 to produce a laminar flow layer and form a gas curtain that flows towards the gas suction unit 308. Thereafter, the nitrogen is returned to the gas pump 302 via the gas suction unit 308. The planar surface of the wafer 400 passes through the spatial gap between the gas outflow unit 306 and the gas suction unit 308 in parallel to the flow direction (arrow 410) of nitrogen. Hence, the upper and lower surface of the wafer will be blown by the curtain of nitrogen and most dust particles or impurities attached to the surface of the wafer 400 will be swept away.

The principle of operating the dust-proof reaction furnace with FOUP door opener can be explained with reference to FIG. 2. The dust-proofing device 216 inside the reaction furnace 200 is in continuous operation and hence dust particles within the reaction furnace 200 are continuously filtered away.

To load the wafers from the FOUP 210 into the reaction chamber 202, the inner door 214 and the outer door 216 of the FOUP door opener 208 are first opened. Thereafter, the robot blade 206 extends into the FOUP 210 to fetch a wafer. The wafer gripped by the robot blade 206 passes through the dust-proofing device on its way to the nitrogen load-lock area 204. Since the curtain of gas provided by the dust-proofing device 216 flows in a direction parallel to the wafer, gas sweeps through the upper and lower surface of the wafer to remove most dust particles. Consequently, very little dust particles are carried into the nitrogen load-lock area 204. Furthermore, the dust-proofing device 216 in the reaction furnace 200 is in continuous operation. Hence, any dust liberated while the outer door 214 and inner door 212 of the FOUP door opener 208 are opened can be swept away by the dust-proofing device 216 without going into the nitrogen load-lock area 204. The robot blade 206 places the wafer on a wafer boat. After moving all the wafers inside the FOUP 210 to the wafer boat, the inner door 212 and the outer door 214 of the FOUP door opener 208 are shut. The aforementioned steps are repeated to bring wafers inside another FOUP into the wafer boat until the entire wafer boat is filled (most wafer boats can accommodates a total of 120 wafers). Finally, the wafer boat is transported into the reaction chamber 202 to carry out the necessary processing reaction.

Similarly, before loading wafers into the FOUP 210, the wafer boat is transported away from the reaction chamber 202. Thereafter, the outer door 214 and the inner door 212 of the FOUP door opener 208 are opened. The robot blade 206 snatches a wafer from the wafer boat and moves the wafer into the FOUP 210 after passing the dust-proofing device 216. Most dust particles liberated as the outer door 214 and the inner door 212 of the FOUP door opener 208 are opened are removed by the dust-proofing device 216 without diffusing into the nitrogen load-lock area 204. After the FOUP 210 is completely filled with wafers, the inner door 212 and the outer door 214 of the FOUP door opener 208 are shut. The aforementioned steps are repeated to move some more wafers inside the wafer boat into another FOUP until all the wafers on the wafer boat are cleared.

In this invention, a dust-proofing device is added to the FOUP door opener of a reaction furnace. The dust-proofing device blows out a layer of gas such as nitrogen to form a curtain. Every wafer going into to out of the FOUP has to pass through the curtain produced by the dust-proofing device so that micro-particles are filtered away. In this way, micro-particles are prevented from entering into the nitrogen load-lock area.

Because every wafer going into or out of the FOUP has to pass through the dust-proofing device, the nitrogen load-lock area (low oxygen area) is little affected by a not-so-tight seal between the FOUP door opener and the FOUP. Hence, a strong clamp for binding the FOUP door opener and the FOUP together is unnecessary.

In addition, by installing a dust-proofing device on the FOUP door opener of a reaction furnace, a wafer may be directly transferred from the FOUP to the wafer boat or vice versa by going through the dust-proofing device. There is no need to purge the FOUP with nitrogen for some time every time a wafer is delivered. Ultimately, nitrogen consumption is reduced, time is saved and productivity is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A front opening unified pod (FOUP) door opener with dust-proof device for opening up a door to a processing station so that a wafer may be transferred from a FOUP into the processing station and vice versa, the FOUP door opener at least comprising:
an inner door setup close to the FOUP; and
a dust-proofing device setup close to the processing station, the dust-proofing device further comprising:
a gas pump for pumping gases;
a gas filter having a gas inlet port connected to the gas outlet port of the gas pump for filtering out dust particles suspended in the gas;
a gas outflow unit connected to the gas outlet port of the gas filter, wherein the gas outflow unit blows out a laminar layer of gas; and
a gas inflow unit connected to the gas inlet port of the gas pump so that the gas blown out from the gas outflow unit is able to return to the gas pump via the gas inflow device,
wherein the gas outflow unit and the gas inflow unit are set up facing each other with a spatial gap between the two, wherein the spatial gap is a channel for wafers going in and out of the FOUP and that a curtain of gas flowing from the gas outflow unit to the gas inflow unit is parallel to the surfaces of the wafers so that the gas sweeps over the upper and lower surface of the wafers.

2. The FOUP door opener of claim 1, wherein the space between the inner door and the dust-proofing device further includes an outer door.

3. The FOUP door opener of claim 1, wherein the gas outflow unit includes a plurality of small pipelines therein.

4. The FOUP door opener of claim 1, wherein the gas pump includes an air-blow drum.

5. The FOUP door opener of claim 1, wherein the processing station includes a reaction furnace.

6. The FOUP door opener of claim 1, wherein the gas includes nitrogen.

7. A dust-proofing device setup next to the wafer entrance of a processing station, the dust-proofing device comprising:
a gas pump for pumping gases;
a gas filter having a gas inlet port connected to the gas outlet port of the gas pump, wherein the gas filter removes dust particles suspended in the gas;
a gas outflow unit connected to the gas outlet port of the gas filter, wherein the gas outflow device blows out a laminar layer of gas; and
a gas inflow device connected to the gas inlet port of the gas pump, wherein the gas blown out of the gas outflow unit is returned to the gas pump via the gas inflow unit;
wherein the gas outflow unit and the gas inflow unit are setup facing each other with a spatial gap between the two, the spatial gap is a channel for wafers going into or out of the processing station, a curtain formed by blowing from the gas outflow unit to the gas inflow unit flows in a direction parallel to the surfaces of the wafers so that the fluid is able to sweep over the upper and lower surface of the wafers.

8. The dust-proofing device of claim 7, wherein the gas outflow unit further includes a plurality of small pipelines therein.

9. The dust-proofing device of claim 7, wherein the gas pump includes an air-blow drum.

10. The dust-proofing device of claim 7, wherein the processing station includes a reaction furnace.

11. The dust-proofing device of claim 7, wherein the gas includes nitrogen.
